(19) United States
(12) Patent Application Publication
(10) Pub. No.: US 2025/0069773 A1
(43) Pub. Date: Feb. 27, 2025

(54) DIELECTRIC MATERIAL AND FUNCTIONAL ELEMENT

(71) Applicant: Panasonic Intellectual Property Management Co., Ltd., Osaka (JP)

(72) Inventors: Hiroki TAKEUCHI, Osaka (JP); Kota MORIMOTO, Osaka (JP); Ryosuke KIKUCHI, Osaka (JP); Hideaki ADACHI, Osaka (JP)

(21) Appl. No.: 18/947,897

(22) Filed: Nov. 14, 2024

Related U.S. Application Data
(63) Continuation of application No. PCT/JP2023/012972, filed on Mar. 29, 2023.

(30) Foreign Application Priority Data
May 17, 2022 (JP) 2022-080662

(51) Int. Cl. H01B 3/10

(52) U.S. Cl. CPC H01B 3/10

(57) ABSTRACT

A dielectric material 1a includes a metal oxide including: Zn; a rare-earth element; and Mn.

This application is a continuation of PCT/JP2023/012972 filed on Mar. 29, 2023, which claims foreign priority of Japanese Patent Application No. 2022-080662 filed on May 17, 2022, the entire contents of both of which are incorporated herein by reference.

### BACKGROUND OF THE INVENTION

### 1. Field of the Invention

The present invention relates to a dielectric material and a functional device.

### 2. Description of Related Art

Conventionally, materials such as barium titanate BaTiO₃, lead zirconate titanate Pb(Zr,Ti)O₃, (Pb,La)(Zr,Ti)O₃, and BiFeO₃ are known as ferroelectric dielectric materials. (Zr,Ti) means that at least one selected from the group consisting of Zr and Ti is included, and (Pb,La) means that at least one selected from the group consisting of Pb and La is included. These dielectric materials are composite oxides having a perovskite structure.

Meanwhile, according to recent reports, an oxide in which part of Zn in ZnO having a wurtzite structure is substituted with a particular element is ferroelectric. Note that ZnO is paraelectric. For example, according to K. Ferri, et al., Journal of Applied Physics 130, 044101 (2021) (Non Patent Literature 1), a thin Zn₁₋ₓMgₓO film is ferroelectric when x is 0.34 to 0.37.

### SUMMARY OF THE INVENTION

The technique described in Non Patent Literature 1 leaves room for further investigation for exhibition of a given dielectric property without using Mg as an element substituted for part of Zn in ZnO. Thus, the present disclosure provides a new dielectric material including a metal oxide including: Zn; and elements other than Mg.

A dielectric material of the present disclosure includes a metal oxide including: Zn; a rare-earth element; and Mn.

The present disclosure can provide a new dielectric material including Zn and elements other than Mg.

### BRIEF DESCRIPTION OF THE DRAWINGS

FIG. 1 is a cross-sectional view showing an example of a dielectric material of the present disclosure.

FIG. 2 schematically shows another example of the dielectric material of the present disclosure.

FIG. 3 schematically shows an example of a functional device of the present disclosure.

FIG. 4 shows an X-ray diffraction (XRD) pattern of a sample according to Example 1.

FIG. 5 is a graph showing a relation between polarization and electric field strength in a metal oxide film of the sample according to Example 1.

FIG. 6 is a graph showing a relation between polarization and electric field strength in a metal oxide film of a sample according to Comparative Example 1.

FIG. 7 is a graph showing a relation between polarization and electric field strength in a metal oxide film of a sample according to Comparative Example 2.

FIG. 8 is a graph showing a relation between a composition ratio of Mn and a composition ratio of a rare-earth element in each of metal oxides of samples according to Examples 1 to 8 and Comparative Examples 2 to 11.

### DETAILED DESCRIPTION

### Findings on Which the Present Disclosure is Based

According to Non Patent Literature 1, a thin Zn₁₋ₓMgₓO film is ferroelectric when x is 0.34 to 0.37. However, it has not been confirmed that an oxide including Zn exhibits a given dielectric property such as ferroelectricity without Mg. Therefore, the present inventors made intensive investigations whether an oxide including Zn can exhibit a given dielectric property such as ferroelectricity without Mg. As a result, the present inventors newly found that a metal oxide including Zn and given metal elements other than Mg can exhibit a given dielectric property such as ferroelectricity. The present inventors have invented the dielectric material of the present disclosure on the basis of this new finding.

### Summary of Aspects According to the Present Disclosure

A dielectric material according to a first aspect of the present disclosure includes a metal oxide including: Zn; a rare-earth element; and Mn.

According to the first aspect, the metal oxide includes a rare-earth element and Mn in addition to Zn, and a given dielectric property such as ferroelectricity is exhibited without Mg in the metal oxide. Therefore, a new dielectric material including a metal oxide including Zn and elements other than Mg can be provided.

According to a second aspect of the present disclosure, for example, in the dielectric material according to the first aspect, the metal oxide may be ferroelectric. According to the second aspect, a new ferroelectric dielectric material can be provided.

According to a third aspect of the present disclosure, for example, in the dielectric material according to the first or second aspect, the rare-earth element may be at least one selected from the group consisting of Nd and Y. According to the third aspect, a new dielectric material including a metal oxide having a given dielectric property such as ferroelectricity can be provided by using Mn and at least one selected from the group consisting of Nd and Y as elements other than Mg.

According to a fourth aspect of the present disclosure, for example, in the dielectric material according to the first or second aspect, the rare-earth element may be Nd. According to the fourth aspect, a new dielectric material including a metal oxide having a given dielectric property such as ferroelectricity can be provided by using Nd and Mn as elements other than Mg.

According to a fifth aspect of the present disclosure, for example, in the dielectric material according to any one of the first to fourth aspects, the metal oxide may have a composition represented by Zn_{1-x-y}AₓMn_{y}O_{z}. In the composition, A may be the rare-earth element. In the composition, z may be for electroneutrality of the metal oxide. The composition may satisfy requirements 0.025≤x≤0.05 and 0.7≤y/x≤1.5. According to the fifth aspect, the metal oxide has a given dielectric property such as ferroelectricity even when the amount of the rare-earth element and the amount of Mn in the metal oxide are small. Hence, compared to the case where part of Zn in ZnO is substituted with Mg for exhibition of a given dielectric property such as ferroelectricity, the amount of metal elements other than Zn in the metal oxide having the given dielectric property such as ferroelectricity can be decreased.

According to a sixth aspect of the present disclosure, for example, in the dielectric material according to any one of the first to fifth aspects, the metal oxide may have a wurtzite structure. According to the sixth aspect, the metal oxide is likely to have a desired ferroelectricity.

According to a seventh aspect of the present disclosure, for example, the dielectric material according to any one of the first to sixth aspects may include: a plurality of crystal grains including the metal oxide; and a filler including an inorganic oxide different from the metal oxide, the filler filling a space between the crystal grains. According to the seventh aspect, the dielectric material is likely to have properties suitable for capacitors.

A functional device according to an eighth aspect of the present disclosure includes:
a dielectric including the dielectric material according to any one of the first to seventh aspects; and
a pair of electrode.

According to the eighth aspect, a functional device taking advantage of a dielectric property, such as ferroelectricity, of the metal oxide included in the dielectric material can be provided.

According to a ninth aspect of the present disclosure, for example, the functional device according to the eighth aspect may be at least one selected from the group consisting of a capacitor, an electro-optic device, a memory device, a transistor, a ferroelectric data storage, a piezoelectric device, and a pyroelectric device. According to the ninth aspect, a functional device, such as a capacitor, taking advantage of a dielectric property, such as ferroelectricity, of the metal oxide included in the dielectric material can be provided.

According to a tenth aspect of the present disclosure, for example, the functional device according to the eighth aspect may be configured to be mounted in at least one selected from the group consisting of an actuator, an inkjet head, a gyroscope sensor, a vibration energy harvester, a surface acoustic wave resonator, a film bulk acoustic resonator, a piezoelectric mirror, and a piezoelectric sensor. According to the tenth aspect, an actuator or the like can take advantage of a dielectric property, such as ferroelectricity, of the metal oxide included in the dielectric material.

### Embodiments

Embodiments of the present disclosure will be described with reference to the drawings.

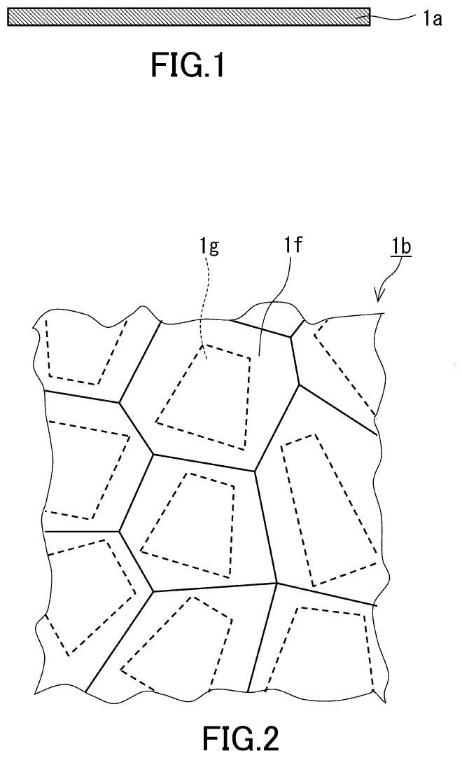

FIG. 1 is a cross-sectional view showing an example of the dielectric material of the present disclosure. As shown in FIG. 1, a dielectric material 1a is, for example, in a film shape. The dielectric material 1a may be in a shape other than a film shape, and may be, for example, in the shape of a cylinder, a powder, or a line.

The dielectric material 1a includes a metal oxide including: Zn; a rare-earth element; and Mn. The metal oxide is, for example, free of Mg. The metal oxide has a given dielectric property such as ferroelectricity even when the metal oxide is free of Mg. The metal oxide may include Mg, if necessary. It is thought that since the metal oxide includes the rare-earth element and Mn as well as Zn, a crystal of the metal oxide is likely to be formed so as to cause spontaneous polarization. For example, it is thought that the crystal is likely to be long in the c-axis direction of a unit lattice of the crystal.

In the dielectric material 1a, a dielectric property of the metal oxide is not limited to a particular dielectric property. The metal oxide of the dielectric material 1a is, for example, ferroelectric.

The above metal oxide can have a given dielectric property such as ferroelectricity even when the amounts of metal elements other than Zn in the metal oxide are small. Because of this, the metal oxide has little variation in terms of its composition and its crystal structure, and thus the above metal oxide is advantageous also in terms of reproducibility. Additionally, even when the metal oxide is free of a toxic element such as Pb, spontaneous polarization of the metal oxide is likely to be large.

The rare-earth element of the metal oxide is not limited to a particular rare-earth element. The rare-earth element of the metal oxide is, for example, at least one selected from the group consisting of Nd and Y. In this case, the metal oxide is likely to have a desired ferroelectricity. The rare-earth element of the metal oxide may be an element other than Nd or Y. Values of ionic radii of ions derived from rare-earth elements are close to each other, as shown in Table 1. It is therefore thought that even when the rare-earth element of the metal oxide is an element other than Nd or Y, a crystal of the metal oxide is likely to be formed so as to cause spontaneous polarization. The rare-earth element of the metal oxide may be at least one selected from the group consisting of Y, La, Ce, Pr, and Nd. The ionic radii shown in Table 1 are the Shannon ionic radii reported in R. D. Shannon, Acta Crystallogr. Sect. A, 32, 751 (1976).

TABLE 1

| Element | Ion | Ionic radius 6-coordinate [Å] |
|---|---|---|
| Sc | Sc³⁺ | 7.45 |
| Y | Y³⁺ | 9.00 |
| La | La³⁺ | 10.32 |
| Ce | Ce³⁺ | 10.1 |
| Pr | Pr³⁺ | 9.9 |
| Nd | Nd³⁺ | 9.83 |
| Pm | Pm³⁺ | 9.7 |
| Sm | Sm³⁺ | 9.58 (4-coordinate) |
| Eu | Eu³⁺ | 9.47 |
| Gd | Gd³⁺ | 9.38 |
| Tb | Tb³⁺ | 9.23 |
| Dy | Dy³⁺ | 9.12 |
| Ho | Ho³⁺ | 9.01 |
| Er | Er³⁺ | 8.90 |
| Tm | Tm³⁺ | 8.80 |
| Yb | Yb³⁺ | 8.68 |
| Lu | Lu³⁺ | 8.61 |

The rare-earth element of the metal oxide is desirably Nd. In this case, the metal oxide is more likely to have a desired ferroelectricity.

The composition of the metal oxide is not limited to a particular composition as long as the metal oxide includes Zn, the rare-earth element, and Mn. The metal oxide has, for example, a composition represented by Zn_{1-x-y}AₓMn_{y}O_{z}. In this composition, A is the rare-earth element, and z is for electroneutrality of the metal oxide. This composition satisfies requirements 0.025≤x≤0.05 and 0.7≤y/x≤1.5. The metal oxide having such a composition has a given dielectric property such as ferroelectricity even when the amounts of the rare-earth element and Mn in the metal oxide are small. Compared to the case where part of Zn in ZnO is substituted with Mg for exhibition of a given dielectric property such as ferroelectricity, the amounts of metal elements other than Zn in the metal oxide having the given dielectric property such as ferroelectricity can be decreased.

In the above composition, z can vary depending on the amounts of the rare-earth element A and Mn and a production process of the dielectric material 1a. For example, z satisfies a requirement 0.9≤z≤1.1.

The crystal structure of the metal oxide is not limited to a particular crystal structure as long as the metal oxide includes Zn, the rare-earth element, and Mn. The metal oxide has, for example, a wurtzite structure. In this case, the metal oxide is likely to have a desired ferroelectricity. For example, remanent polarization in the metal oxide is likely to be large.

The dielectric material 1a is configured, for example, as a material consisting of the metal oxide. The dielectric material 1a may be configured as a composite material including the metal oxide. FIG. 2 schematically shows another example of the dielectric material of the present disclosure. The dielectric material 1a may be modified, for example, to a dielectric material 1b shown in FIG. 2.

The method for producing the dielectric material 1a is not limited to a particular method. The dielectric material 1a can be produced, for example, by a vacuum process such as RF magnetron sputtering, pulsed laser deposition (PLD), atomic layer deposition (ALD), or chemical vapor deposition (CVD). The dielectric material 1a may be produced by a wet process such as chemical solution deposition (CSD), a sol-gel process, or a hydrothermal method.

As shown in FIG. 2, the dielectric material 1b includes a plurality of crystal grains 1g and a filler 1f. The crystal grain 1g includes the above metal oxide. The filler 1f includes an inorganic oxide different from the above metal oxide, and fills a space between the crystal grains 1g. The dielectric material 1b configured as above is likely to have properties suitable for capacitors.

The method for producing the dielectric material 1b is not limited to a particular method. The dielectric material 1b is produced, for example, by the following method. First, a binder and a powder composed of raw materials of the above metal oxide and a raw material of the filler 1f are mixed to give a mixture. This mixture is formed into a sheet shape by a method such as screen printing to give a green sheet. The dielectric material 1b can be produced by baking this green sheet.

A given functional device can be provided using the dielectric material 1a or 1b. FIG. 3 schematically shows an example of the functional device of the present disclosure. As shown in FIG. 3, a functional device 2 includes, for example, a dielectric 10 and a pair of electrodes 20. The dielectric 10 includes the dielectric material 1a. The dielectric 10 may include the dielectric material 1b. Since the functional device 2 includes the dielectric 10, the functional device 2 can be used in applications where the functional device 2 takes advantage of a dielectric property, such as ferroelectricity, of the metal oxide included in the dielectric material 1a of the dielectric 10.

As shown in FIG. 3, in the functional device 2, the dielectric 10 is disposed, for example, between the pair of electrodes 20.

The functional device 2 is not limited to a particular device. The functional device 2 is, for example, at least one selected from the group consisting of a capacitor, an electro-optic element, a memory device, a transistor, a ferroelectric data storage, a piezoelectric device, and a pyroelectric device. For example, these functional devices can take advantage of a dielectric property, such as ferroelectricity, of the metal oxide included in the dielectric material 1a of the dielectric 10.

The functional device 2 is configured to be mounted in, for example, at least one selected from the group consisting of an actuator, an inkjet head, a gyroscope sensor, a vibration energy harvester, a surface acoustic wave resonator, a film bulk acoustic resonator, a piezoelectric mirror, and a piezoelectric sensor. In this case, an actuator or the like can take advantage of a piezoelectric effect attributable to a dielectric property of the metal oxide included in the dielectric material 1a of the dielectric 10.

### EXAMPLES

The present disclosure will be hereinafter described in more detail using examples. The present disclosure is not limited to examples given below.

### Example 1

A 100 nm-thick Pt (111) film was epitaxially grown on a c-plane single-crystal sapphire substrate by RF magnetron sputtering to give a Pt electrode. Next, a 200 nm-thick metal oxide film was formed on the Pt electrode by RF magnetron sputtering. The metal oxide film included Zn, Nd, and Mn as metals. In the metal oxide film, a ratio of the number of Nd atoms to the (total) number of Zn, Nd, and Mn atoms was 0.045. In the metal oxide film, a ratio of the number of Mn atoms to the (total) number of Zn, Nd, and Mn atoms was 0.042. In this RF magnetron sputtering, a composite oxide including Zn, Nd, and Mn was used as a target. This target satisfied the following requirement: the number of Zn atoms: the number of Nd atoms: the number of Mn atoms=1:0.87:0.05. Additionally, in this RF magnetron sputtering, the Pt electrode was heated at 300° C. in an atmosphere where 25 vol % oxygen and argon were mixed. Next, a 100 nm-thick Au film was formed on the metal oxide film by vacuum deposition to give an Au electrode. A sample according to Example 1 was obtained in this manner.

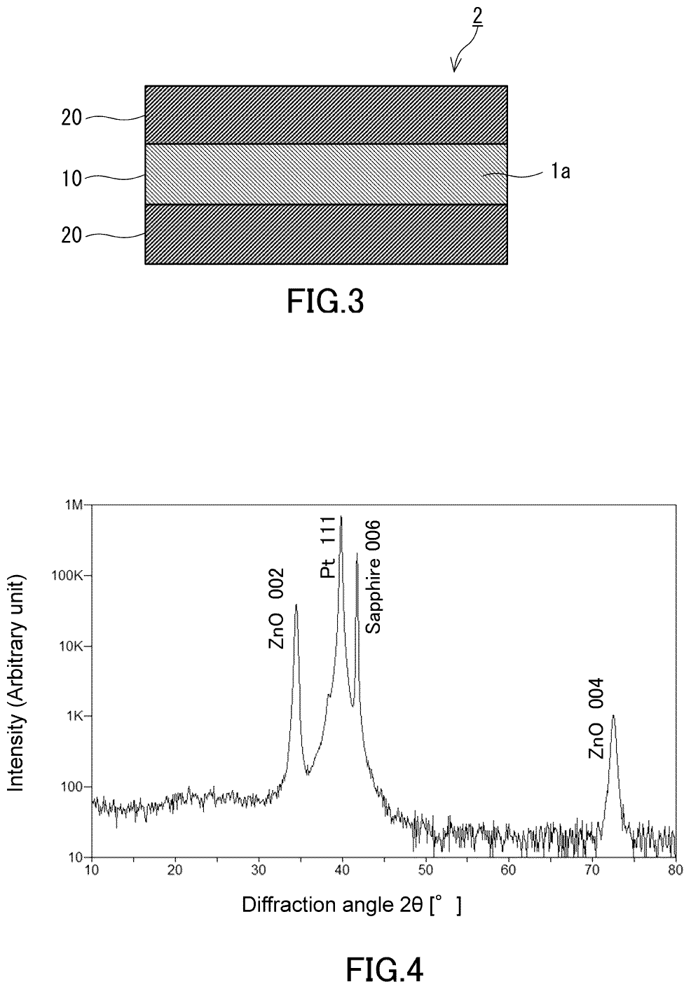

The crystal structure of the metal oxide film of the sample according to Example 1 was evaluated using an X-ray diffraction (XRD) apparatus X'Pert Pro MPD manufactured by Malvern Panalytical Ltd. A Cu-Kα ray (wavelength λ=0.15418 nm) was used as an X-ray for XRD. FIG. 4 shows an XRD pattern of the sample according to Example 1. According to FIG. 4, in addition to a diffraction peak derived from the substrate, a diffraction peak derived from the (00L) plane of a wurtzite structure appears with a high intensity. This confirms that the metal oxide film of the sample according to Example 1 had a wurtzite structure and that the metal oxide film epitaxially grew such that the c plane of the wurtzite structure was parallel to the substrate.

The composition of the metal oxide film of the sample according to Example 1 was determined using an X-ray photoelectron spectroscopy (XPS) apparatus ESCA 5600 manufactured by ULVAC PHI, INC. Table 2 shows a ratio x of the number of atoms of the rare-earth element and a ratio y of the number of Mn atoms to the total number of Zn atoms, atoms of the rare-earth element, and Mn atoms in the metal oxide film.

Polarization-electric field measurement was performed for the sample according to Example 1 using a ferroelectric tester Premier II manufactured by Radiant Technologies, Inc. to obtain a P-E curve of the sample according to Example 1. Dielectric properties of the metal oxide of the sample according to Example 1 were evaluated on the basis of this P-E curve. Table 2 shows the results. In Table 2, an “A” rating for evaluation of electrical insulation means that the metal oxide has good electrical insulation. An “X” rating for evaluation of electrical insulation means that the metal oxide is electrically conductive. An “A” rating for evaluation of ferroelectricity means that the metal oxide is ferroelectric. An “X” rating for evaluation of ferroelectricity means that the metal oxide is not ferroelectric. The metal oxide film of the sample according to Example 1 was confirmed to have good electrical insulation and be a ferroelectric exhibiting a high polarization.

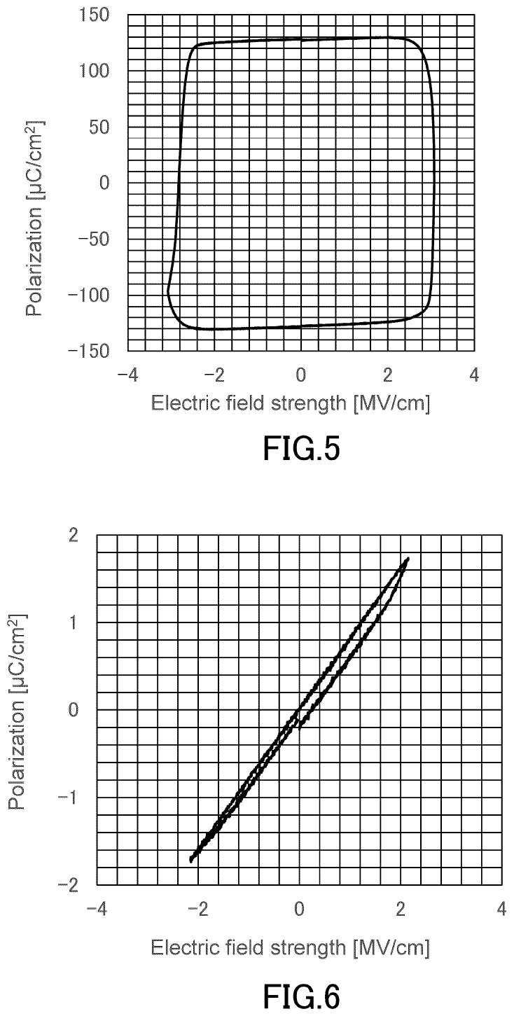

FIG. 5 shows the P-E curve of the sample according to Example 1, and shows a relation between polarization and electric field strength in the metal oxide film. In FIG. 5, the vertical axis represents polarization, and the horizontal axis represents electric field strength. As shown in FIG. 5, the metal oxide film of the sample according to Example 1 showed a remanent polarization of approximately 130 μC/cm², which confirms that the metal oxide film is a ferroelectric exhibiting a high polarization.

### Example 2

A sample according to Example 2 was produced in the same manner as in Example 1, except that the composite oxide target was changed to satisfy the following requirement: the number of Zn atoms: the number of Nd atoms: the number of Mn atoms=1:0.53:0.05. The crystal structure of the metal oxide film of the sample according to Example 2 was evaluated in the same manner as in Example 1. The evaluation confirmed that the metal oxide film of the sample according to Example 2 had a wurtzite structure and that the metal oxide film epitaxially grew such that the c plane of the wurtzite structure was parallel to the substrate. The composition of the metal oxide film of the sample according to Example 2 was determined in the same manner as in Example 1. Table 2 shows the result. The dielectric properties of the metal oxide film of the sample according to Example 2 were evaluated in the same manner as in Example 1. Table 2 shows the results. The metal oxide film of the sample according to Example 2 was confirmed to have good electrical insulation and be a ferroelectric exhibiting a high polarization.

### Example 3

A sample according to Example 3 was produced in the same manner as in Example 1, except that the composite oxide target was changed to satisfy the following requirement: the number of Zn atoms: the number of Nd atoms: the number of Mn atoms=1:0.053:0.04. The crystal structure of the metal oxide film of the sample according to Example 3 was evaluated in the same manner as in Example 1. The evaluation confirmed that the metal oxide film of the sample according to Example 3 had a wurtzite structure and that the metal oxide film epitaxially grew such that the c plane of the wurtzite structure was parallel to the substrate. The composition of the metal oxide film of the sample according to Example 3 was determined in the same manner as in Example 1. Table 2 shows the result. The dielectric properties of the metal oxide film of the sample according to Example 3 were evaluated in the same manner as in Example 1. Table 2 shows the results. The metal oxide film of the sample according to Example 3 was confirmed to have good electrical insulation and be a ferroelectric exhibiting a high polarization.

### Example 4

A sample according to Example 4 was produced in the same manner as in Example 1, except that the composite oxide target was changed to satisfy the following requirement: the number of Zn atoms: the number of Nd atoms: the number of Mn atoms=1:0.087:0.04. The crystal structure of the metal oxide film of the sample according to Example 4 was evaluated in the same manner as in Example 1. The evaluation confirmed that the metal oxide film of the sample according to Example 4 had a wurtzite structure and that the metal oxide film epitaxially grew such that the c plane of the wurtzite structure was parallel to the substrate. The composition of the metal oxide film of the sample according to Example 4 was determined in the same manner as in Example 1. Table 2 shows the result. The dielectric properties of the metal oxide film of the sample according to Example 4 were evaluated in the same manner as in Example 1. Table 2 shows the results. The metal oxide film of the sample according to Example 4 was confirmed to have good electrical insulation and be a ferroelectric exhibiting a high polarization.

### Example 5

A sample according to Example 5 was produced in the same manner as in Example 1, except that the composite oxide target was changed to satisfy the following requirement: the number of Zn atoms: the number of Nd atoms: the number of Mn atoms=1:0.087:0.07. The crystal structure of the metal oxide film of the sample according to Example 5 was evaluated in the same manner as in Example 1. The evaluation confirmed that the metal oxide film of the sample according to Example 5 had a wurtzite structure and that the metal oxide film epitaxially grew such that the c plane of the wurtzite structure was parallel to the substrate. The composition of the metal oxide film of the sample according to Example 5 was determined in the same manner as in Example 1. Table 2 shows the result. The dielectric properties of the metal oxide film of the sample according to Example 5 were evaluated in the same manner as in Example 1. Table 2 shows the results. The metal oxide film of the sample according to Example 5 was confirmed to have good electrical insulation and be a ferroelectric exhibiting a high polarization.

### Example 6

A sample according to Example 6 was produced in the same manner as in Example 1, except that the composite oxide target was changed to satisfy the following requirement: the number of Zn atoms: the number of Nd atoms: the number of Mn atoms=1:0.087:0.08. The crystal structure of the metal oxide film of the sample according to Example 6 was evaluated in the same manner as in Example 1. The evaluation confirmed that the metal oxide film of the sample according to Example 6 had a wurtzite structure and that the metal oxide film epitaxially grew such that the c plane of the wurtzite structure was parallel to the substrate. The composition of the metal oxide film of the sample according to Example 6 was determined in the same manner as in Example 1. Table 2 shows the result. The dielectric properties of the metal oxide film of the sample according to Example 6 were evaluated in the same manner as in Example 1. Table 2 shows the results. The metal oxide film of the sample according to Example 6 was confirmed to have good electrical insulation and be a ferroelectric exhibiting a high polarization.

### Example 7

A sample according to Example 7 was produced in the same manner as in Example 1, except that the composite oxide target was changed to satisfy the following requirement: the number of Zn atoms: the number of Nd atoms: the number of Mn atoms=1:0.053:0.03. The crystal structure of the metal oxide film of the sample according to Example 7 was evaluated in the same manner as in Example 1. The evaluation confirmed that the metal oxide film of the sample according to Example 7 had a wurtzite structure and that the metal oxide film epitaxially grew such that the c plane of the wurtzite structure was parallel to the substrate. The composition of the metal oxide film of the sample according to Example 7 was determined in the same manner as in Example 1. Table 2 shows the result. The dielectric properties of the metal oxide film of the sample according to Example 7 were evaluated in the same manner as in Example 1. Table 2 shows the results. The metal oxide film of the sample according to Example 7 was confirmed to have good electrical insulation and be a ferroelectric exhibiting a high polarization.

### Example 8

A sample according to Example 8 was produced in the same manner as in Example 1, except for the following points. The composite oxide target included Y instead of Nd as a rare-earth element, and satisfied the following requirement: the number of Zn atoms: the number of Y atoms: the number of Mn atoms=1:0.075:0.05. The crystal structure of the metal oxide film of the sample according to Example 8 was evaluated in the same manner as in Example 1. The evaluation confirmed that the metal oxide film of the sample according to Example 8 had a wurtzite structure and that the metal oxide film epitaxially grew such that the c plane of the wurtzite structure was parallel to the substrate. The composition of the metal oxide film of the sample according to Example 8 was determined in the same manner as in Example 1. Table 2 shows the result. The dielectric properties of the metal oxide film of the sample according to Example 8 were evaluated in the same manner as in Example 1. Table 2 shows the results. The metal oxide film of the sample according to Example 8 was confirmed to have good electrical insulation and be a ferroelectric exhibiting a high polarization.

### Comparative Example 1

A sample according to Comparative Example 1 was produced in the same manner as in Example 1, except for the following points. The composite oxide target was free of rare-earth elements, included Mg, and satisfied the following requirement: the number of Zn atoms: the number of Mg atoms: the number of Mn atoms=1:0.55:0.02. The dielectric properties of the metal oxide film of the sample according to Comparative Example 1 were evaluated in the same manner as in Example 1. Table 2 shows the results. FIG. 6 is a graph showing a relation between polarization and electric field strength in the metal oxide film of the sample according to Comparative Example 1. As shown in FIG. 6, although having good electrical insulation, the metal oxide film of the sample according to Comparative Example 1 had a dielectric property of a paraelectric and was not a ferroelectric.

### Comparative Example 2

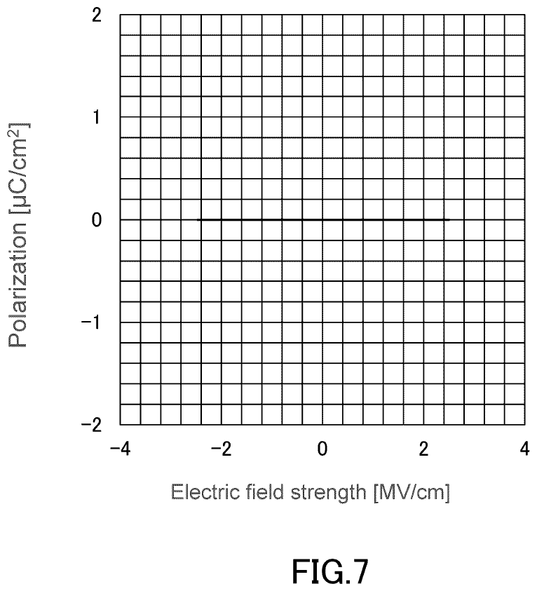

A sample according to Comparative Example 2 was produced in the same manner as in Example 1, except that the composite oxide target was changed to satisfy the following requirement: the number of Zn atoms: the number of Nd atoms: the number of Mn atoms=1:0.053:0.02. The composition of the metal oxide film of the sample according to Comparative Example 2 was determined in the same manner as in Example 1. Table 2 shows the result. The dielectric properties of the metal oxide film of the sample according to Comparative Example 2 were evaluated in the same manner as in Example 1. Table 2 shows the results. FIG. 7 is a graph showing a relation between polarization and electric field strength in the metal oxide film of the sample according to Comparative Example 2. As shown in FIG. 7, the metal oxide film of the sample according to Comparative Example 2 was electrically conductive, and leakage current was large in the measurement for a P-E curve.

### Comparative Example 3

A sample according to Comparative Example 3 was produced in the same manner as in Example 1, except that the composite oxide target was changed to satisfy the following requirement: the number of Zn atoms: the number of Nd atoms: the number of Mn atoms=1:0.087:0.03. The composition of the metal oxide film of the sample according to Comparative Example 3 was determined in the same manner as in Example 1. Table 2 shows the result. The dielectric properties of the metal oxide film of the sample according to Comparative Example 3 were evaluated in the same manner as in Example 1. Table 2 shows the results. The metal oxide film of the sample according to Comparative Example 3 was electrically conductive, and leakage current was large in the measurement for a P-E curve.

### Comparative Example 4

A sample according to Comparative Example 4 was produced in the same manner as in Example 1, except that the composite oxide target was changed to satisfy the following requirement: the number of Zn atoms: the number of Nd atoms: the number of Mn atoms=1:0.031:0.03. The composition of the metal oxide film of the sample according to Comparative Example 4 was determined in the same manner as in Example 1. Table 2 shows the result. The dielectric properties of the metal oxide film of the sample according to Comparative Example 4 were evaluated in the same manner as in Example 1. Table 2 shows the results. The metal oxide film of the sample according to Comparative Example 4 was electrically conductive, and leakage current was large in the measurement for a P-E curve.

### Comparative Example 5

A sample according to Comparative Example 5 was produced in the same manner as in Example 1, except that the composite oxide target was changed to satisfy the following requirement: the number of Zn atoms: the number of Nd atoms: the number of Mn atoms=1:0.031:0.04. The composition of the metal oxide film of the sample according to Comparative Example 5 was determined in the same manner as in Example 1. Table 2 shows the result. The dielectric properties of the metal oxide film of the sample according to Comparative Example 5 were evaluated in the same manner as in Example 1. Table 2 shows the results. The metal oxide film of the sample according to Comparative Example 5 was electrically conductive, and leakage current was large in the measurement for a P-E curve.

### Comparative Example 6

A sample according to Comparative Example 6 was produced in the same manner as in Example 1, except that the composite oxide target was changed to satisfy the following requirement: the number of Zn atoms: the number of Nd atoms: the number of Mn atoms=1:0.031:0.05. The composition of the metal oxide film of the sample according to Comparative Example 6 was determined in the same manner as in Example 1. Table 2 shows the result. The dielectric properties of the metal oxide film of the sample according to Comparative Example 6 were evaluated in the same manner as in Example 1. Table 2 shows the results. The metal oxide film of the sample according to Comparative Example 6 was electrically conductive, and leakage current was large in the measurement for a P-E curve.

### Comparative Example 7

A sample according to Comparative Example 7 was produced in the same manner as in Example 1, except that the composite oxide target was changed to satisfy the following requirement: the number of Zn atoms: the number of Nd atoms: the number of Mn atoms=1:0.053:0.06. The composition of the metal oxide film of the sample according to Comparative Example 7 was determined in the same manner as in Example 1. Table 2 shows the result. The dielectric properties of the metal oxide film of the sample according to Comparative Example 7 were evaluated in the same manner as in Example 1. Table 2 shows the results. The metal oxide film of the sample according to Comparative Example 7 was electrically conductive, and leakage current was large in the measurement for a P-E curve.

### Comparative Example 8

A sample according to Comparative Example 8 was produced in the same manner as in Example 1, except that the composite oxide target was changed to satisfy the following requirement: the number of Zn atoms: the number of Nd atoms: the number of Mn atoms=1:0.053:0.07. The composition of the metal oxide film of the sample according to Comparative Example 8 was determined in the same manner as in Example 1. Table 2 shows the result. The dielectric properties of the metal oxide film of the sample according to Comparative Example 8 were evaluated in the same manner as in Example 1. Table 2 shows the results. The metal oxide film of the sample according to Comparative Example 8 had a low electrical insulation and was electrically conductive, and leakage current was large in the measurement for a P-E curve.

### Comparative Example 9

A sample according to Comparative Example 9 was produced in the same manner as in Example 1, except that the composite oxide target was changed to satisfy the following requirement: the number of Zn atoms: the number of Nd atoms: the number of Mn atoms=1:0.11:0.07. The composition of the metal oxide film of the sample according to Comparative Example 9 was determined in the same manner as in Example 1. Table 2 shows the result. The dielectric properties of the metal oxide film of the sample according to Comparative Example 9 were evaluated in the same manner as in Example 1. Table 2 shows the results. The metal oxide film of the sample according to Comparative Example 9 had a low electrical insulation and was electrically conductive, and leakage current was large in the measurement for a P-E curve.

### Comparative Example 10

A sample according to Comparative Example 10 was produced in the same manner as in Example 1, except that the composite oxide target was changed to satisfy the following requirement: the number of Zn atoms: the number of Nd atoms: the number of Mn atoms=1:0.11:0.05. The composition of the metal oxide film of the sample according to Comparative Example 10 was determined in the same manner as in Example 1. Table 2 shows the result. The dielectric properties of the metal oxide film of the sample according to Comparative Example 10 were evaluated in the same manner as in Example 1. Table 2 shows the results. The metal oxide film of the sample according to Comparative Example 10 had a low electrical insulation and was electrically conductive, and leakage current was large in the measurement for a P-E curve.

### Comparative Example 11

A sample according to Comparative Example 11 was produced in the same manner as in Example 1, except that the composite oxide target was changed to satisfy the following requirement: the number of Zn atoms: the number of Nd atoms: the number of Mn atoms=1:0.087:0.1. The composition of the metal oxide film of the sample according to Comparative Example 11 was determined in the same manner as in Example 1. Table 2 shows the result. The dielectric properties of the metal oxide film of the sample according to Comparative Example 11 were evaluated in the same manner as in Example 1. Table 2 shows the results. The metal oxide film of the sample according to Comparative Example 11 had a low electrical insulation and was electrically conductive, and leakage current was large in the measurement for a P-E curve.

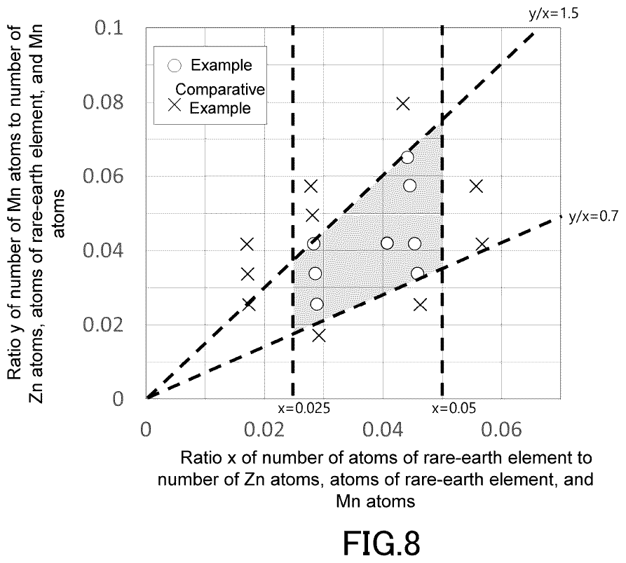

FIG. 8 is a graph showing a relation between the composition ratio y of Mn and the composition ratio x of the rare-earth element in each of the metal oxides of the samples according to Examples 1 to 8 and Comparative Examples 2 to 11. In this graph, “∘” represents an example, while “x” represents a comparative example. As shown in FIG. 8, the metal oxides of the samples according to Examples 1 to 8 satisfy the requirements 0.025≤x≤0.05 and 0.7≤y/x≤1.5. On the other hand, the metal oxides of the samples according to Comparative Examples 2 to 11 do not satisfy both 0.025≤x≤0.05 and 0.7≤y/x≤1.5.

TABLE 2

| | | Ratio x of | | | | |
|---|---|---|---|---|---|---|
| | | number of | | Ratio y of number | | |
| | Element | atoms | Element | of atoms | Electrical | |
| | A | A/(Zn + A + B) | B | B/(Zn + A + B) | insulation | Ferroelectricity |
| Example 1 | Nd | 0.045 | Mn | 0.042 | A | A |
| Example 2 | Nd | 0.028 | Mn | 0.042 | A | A |
| Example 3 | Nd | 0.029 | Mn | 0.034 | A | A |
| Example 4 | Nd | 0.046 | Mn | 0.034 | A | A |
| Example 5 | Nd | 0.045 | Mn | 0.057 | A | A |
| Example 6 | Nd | 0.044 | Mn | 0.065 | A | A |
| Example 7 | Nd | 0.029 | Mn | 0.026 | A | A |
| Example 8 | Y | 0.041 | Mn | 0.042 | A | A |
| Comparative | Mg | 0.37 | Mn | 0.018 | A | X |
| Example 1 | | | | | | Paraelectric |
| Comparative | Nd | 0.029 | Mn | 0.017 | X | — |
| Example 2 | | | | | | |
| Comparative | Nd | 0.046 | Mn | 0.026 | X | — |
| Example 3 | | | | | | |
| Comparative | Nd | 0.017 | Mn | 0.026 | X | — |
| Example 4 | | | | | | |
| Comparative | Nd | 0.017 | Mn | 0.034 | X | — |
| Example 5 | | | | | | |
| Comparative | Nd | 0.017 | Mn | 0.042 | X | — |
| Example 6 | | | | | | |
| Comparative | Nd | 0.028 | Mn | 0.05 | X | — |
| Example 7 | | | | | | |
| Comparative | Nd | 0.028 | Mn | 0.057 | X | — |
| Example 8 | | | | | | |
| Comparative | Nd | 0.056 | Mn | 0.057 | X | — |
| Example 9 | | | | | | |
| Comparative | Nd | 0.057 | Mn | 0.042 | X | — |
| Example 10 | | | | | | |
| Comparative | Nd | 0.043 | Mn | 0.08 | X | — |
| Example 11 | | | | | | |

### INDUSTRIAL APPLICABILITY

The dielectric material of the present disclosure can have a given dielectric property such as ferroelectricity without including Mg as an element substituted for part of Zn in ZnO.

What is claimed is:

1. A dielectric material comprising a metal oxide including: Zn; a rare-earth element; and Mn.

2. The dielectric material according to claim 1, wherein the metal oxide is ferroelectric.

3. The dielectric material according to claim 1, wherein the rare-earth element is at least one selected from the group consisting of Nd and Y.

4. The dielectric material according to claim 1, wherein the rare-earth element is Nd.

5. The dielectric material according to claim 1, wherein
the metal oxide has a composition represented by Zn_{1-x-y}AₓMn_{y}O_{z},
in the composition, A is the rare-earth element,
in the composition, z is for electroneutrality of the metal oxide, and
the composition satisfies requirements 0.025≤x≤0.05 and 0.7≤y/x≤1.5.

6. The dielectric material according to claim 1, wherein the metal oxide has a wurtzite structure.

7. The dielectric material according to claim 1, comprising:
a plurality of crystal grains including the metal oxide; and
a filler including an inorganic oxide different from the metal oxide, the filler filling a space between the crystal grains.

8. A functional device comprising:
a dielectric including the dielectric material according to claim 1; and
a pair of electrodes.

9. The functional device according to claim 8, being at least one selected from the group consisting of a capacitor, an electro-optic device, a memory device, a transistor, a ferroelectric data storage, a piezoelectric device, and a pyroelectric device.

10. The functional device according to claim 8, being configured to be mounted in at least one selected from the group consisting of an actuator, an inkjet head, a gyroscope sensor, a vibration energy harvester, a surface acoustic wave resonator, a film bulk acoustic resonator, a piezoelectric mirror, and a piezoelectric sensor.
